(19) United States
(12) Patent Application Publication
(10) Pub. No.: US 2024/0258039 A1
(43) Pub. Date: Aug. 1, 2024

(54) TUNABLE CAPACITOR

(71) Applicant: Qorvo US, Inc., Greensboro, NC (US)

(72) Inventors: Milad Zolfagharloo Koohi, Longwood, FL (US); Nadim Khlat, Cugnaux (FR); Paul Stokes, Orlando, FL (US)

(21) Appl. No.: 18/383,118

(22) Filed: Oct. 24, 2023

Related U.S. Application Data
(60) Provisional application No. 63/482,165, filed on Jan. 30, 2023.

(51) Int. Cl. H01G 7/06

(52) U.S. Cl. CPC H01G 7/06; H03H 9/542

(57) ABSTRACT

Tunable capacitors based on scandium aluminum nitride (ScAlN) are disclosed. In one aspect, a tunable capacitor or varactor may be formed from a ferroelectric material. More particularly, the ferroelectric material may be formed from ScAlN. The permittivity of the ScAlN material may be adjusted using a direct current (DC) electric field applied to the material. Tunable capacitors or varactors have myriad uses in wireless communication systems, such as being used in filters or transformers. Further, use of ScAlN allows resonators and varactors to be formed on the same die or wafer using the same process flow, thereby reducing cost, fabrication complexity, and also potentially reducing the overall size of the circuit.

### PRIORITY APPLICATION

This application claims the benefit of U.S. Provisional Patent Application Ser. No. 63/482,165, filed on Jan. 30, 2023, entitled “TUNABLE CAPACITOR,” the disclosure of which is hereby incorporated herein by reference in its entirety.

### BACKGROUND

### I. Field of the Disclosure

The technology of the disclosure relates generally to capacitors and particularly to tunable capacitors made from ferroelectric materials.

### II. Background

Computing devices abound in modern society, and more particularly, mobile communication devices have become increasingly common. The prevalence of these mobile communication devices is driven in part by the many functions that are now enabled on such devices. Increased processing capabilities in such devices means that mobile communication devices have evolved from pure communication tools into sophisticated mobile entertainment centers, thus enabling enhanced user experiences. With the advent of the myriad functions available to such devices, there has been increased pressure to find ways to improve data transmission and reception. Various wireless standards continue to evolve using new frequencies and/or new encoding schemes in an effort to improve performance. These evolving standards create opportunities for innovation.

### SUMMARY

Aspects disclosed in the detailed description include a tunable capacitor. In particular, a tunable capacitor or varactor may be formed from a ferroelectric material. More particularly, the ferroelectric material may be formed from scandium aluminum nitride (ScAlN). The permittivity of the ScAlN material may be adjusted using a direct current (DC) electric field applied to the material. Tunable capacitors or varactors have myriad uses in wireless communication systems, such as being used in filters or transformers. Further, use of ScAlN allows resonators and varactors to be formed on the same die or wafer as other circuits or elements, using the same process flow, thereby reducing cost, fabrication complexity, and also potentially reducing the overall size of the circuit.

In this regard, in one aspect, a varactor is disclosed. The varactor comprises a ferroelectric material comprising ScAlN, a first electrode applied to the ferroelectric material, and a second electrode applied to the ferroelectric material.

In another aspect, a method of fabricating a die is disclosed. The method comprises forming a varactor using a first ferroelectric material on a substrate. The method also comprises forming a resonator using a second ferroelectric material on the substrate.

In another aspect, a mobile terminal is disclosed. The mobile terminal includes a transceiver comprising a varactor. The varactor includes a ferroelectric material comprising scandium aluminum nitride (ScAlN), a first electrode applied to the ferroelectric material, and a second electrode applied to the ferroelectric material.

### BRIEF DESCRIPTION OF THE DRAWINGS

FIG. 1 is a side elevation view of a tunable capacitor (varactor) according to an exemplary aspect of the present disclosure;

FIG. 2A is a graph showing a polarization of a scandium aluminum nitride (ScAlN) material;

FIG. 2B is a graph showing permittivity for the ScAlN material as a function of an electric field;

FIG. 3 is a graph of capacitance as a function of voltage for an exemplary ScAlN capacitor of the present disclosure;

FIG. 4A shows a side elevation of an alternate electrode structure for a ScAlN capacitor;

FIG. 4B shows a side elevation of another alternate electrode structure for a ScAlN capacitor;

FIG. 4C shows a side elevation of another alternate electrode structure having vertical electrodes for a ScAlN capacitor;

FIG. 5 shows two ScAlN varactors connected in series with a direct current (DC) bias in a middle node;

FIG. 6 shows a block diagram of a possible use case in a filter for a ScAlN varactor according to an exemplary aspect of the present disclosure; and

FIG. 7 is a block diagram of a mobile terminal, which may include a filter, resonator, or other structure having a ScAlN varactor according to the present disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Aspects disclosed in the detailed description include a tunable capacitor. In particular, a tunable capacitor or varactor may be formed from a ferroelectric material. More particularly, the ferroelectric material may be formed from scandium aluminum nitride (ScAlN). The permittivity of the ScAlN material may be adjusted using a direct current (DC) electric field applied to the material. Tunable capacitors or varactors have myriad uses in wireless communication systems such as being used in filters or transformers. Further, use of ScAlN allows resonators and varactors to be formed on the same die or wafer as other circuits or elements, using the same process flow, thereby reducing cost, fabrication complexity, and also potentially reducing the overall size of the circuit.

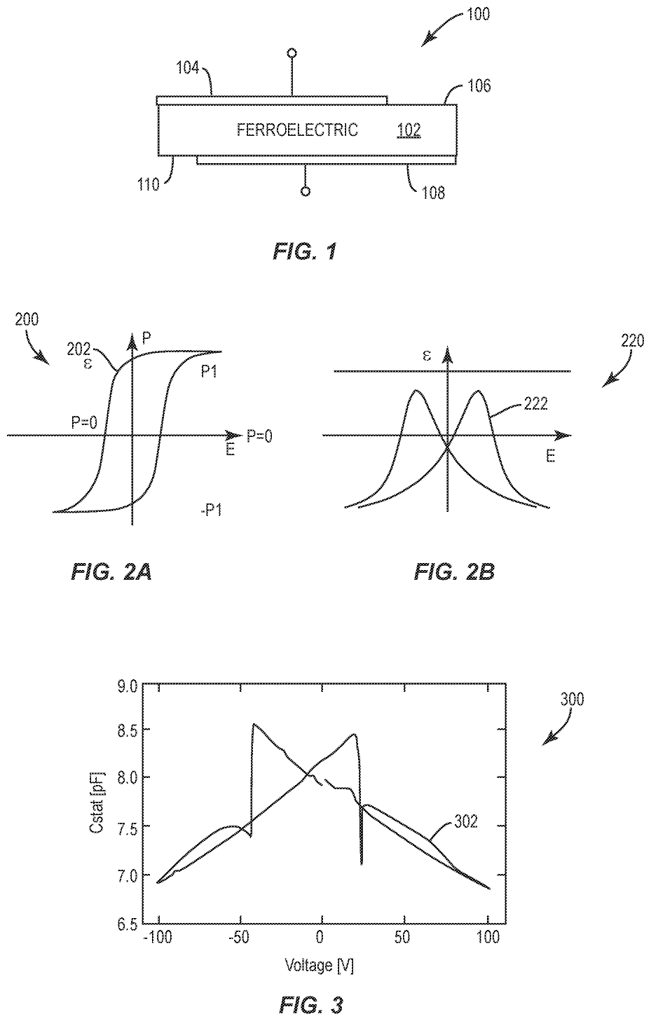

The basic structure of a capacitor has been known for many years. A dielectric material is positioned between two electrodes. The present disclosure contemplates using ScAlN as the dielectric material. In this regard, FIG. 1 is side elevation view of a first variable capacitor or varactor 100 according to an exemplary aspect of the present disclosure. Specifically, the varactor 100 includes a ferroelectric dielectric 102 formed from ScAlN with a first electrode 104 on a first surface 106 and a second electrode 108 on second surface 110. The first surface 106 is opposite the second surface 110. In an exemplary aspect, the first electrode 104 and the second electrode 108 are formed from a metal such as copper, silver, gold, platinum, or aluminum and configured to conduct current therethrough. The electrodes 104 and 108 are applied to the respective surfaces 106 and 110 and may be secured thereto through any conventional means.

The specific dimensions of the ferroelectric dielectric 102 and the electrodes 104, 108 are not central to the present disclosure and may be varied by designers with the assistance of modeling software to determine an optimal size and shape. However, the general properties of a ScAlN material are provided with reference to graphs 200 and 220 in FIGS. 2A and 2B, respectively. Specifically, graph 200 shows a polarization curve 202 for a ScAlN material against permittivity. Graph 220 shows permittivity versus an electric field E curve 222.

These attributes shown in the graphs 200, 220 allow creation of a capacitor 100 having a voltage-dependent capacitance, as shown by curve 302 in graph 300 of FIG. 3, where voltage is along the x-axis and capacitance is along the y-axis. In use, a DC bias may be provided to the ScAlN material, thereby setting the polarity and permittivity, which allows the capacitance to be selected. It should be appreciated that the curve 302 is exemplary and specific curves for different geometries may differ. However, in all instances, it should be further appreciated that the capacitance is a function of voltage, and this knowledge may be used to help implement aspects of the present disclosure.

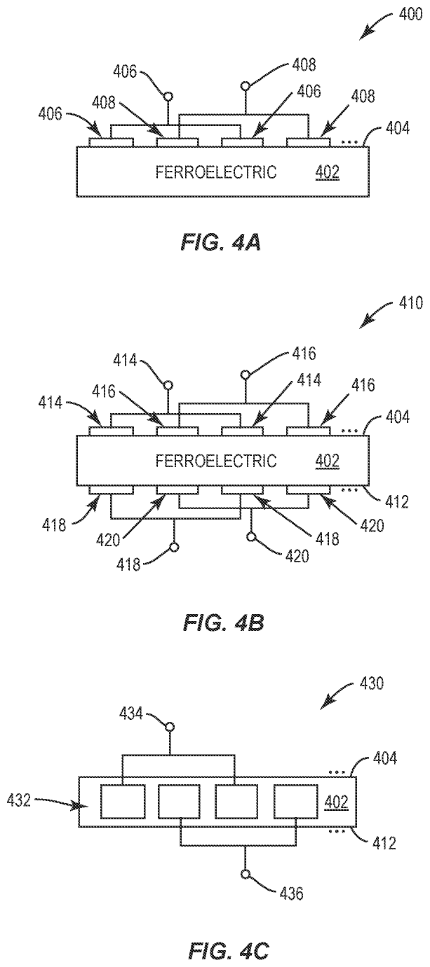

While FIG. 1 shows one possible structure (e.g., a metal-insulator-metal (MIM)) for a varactor made of ScAlN, there are other structures contemplated by the present disclosure including, but not necessarily limited to, interdigitated structures as better seen in FIGS. 4A-4C. Specifically, FIG. 4A shows a varactor 400 having a ScAlN ferroelectric material 402 having a first or top surface 404. Electrodes 406 and 408 are formed on the top surface 404 in an alternating or interdigitated manner.

FIG. 4B shows a varactor 410 having a ScAlN ferroelectric material 402 having a first or top surface 404 and a second or bottom surface 412. Electrodes 414 and 416 are interdigitated on the top surface 404 and electrodes 418 and 420 are interdigitated on the bottom surface 412.

FIG. 4C shows a varactor 430 having an ScAlN ferroelectric material 402 having a vertical side 432 with electrodes 434, 436 interdigitated thereon. While only one vertical side 432 is shown as having electrodes 434, 436 thereon, other vertical sides could also have electrodes thereon. It should be appreciated that “vertical” in this context is referential and is not intended to be limiting. More accurately, the vertical side 432 could be called another surface perpendicular to the top surface 404 or the bottom surface 412.

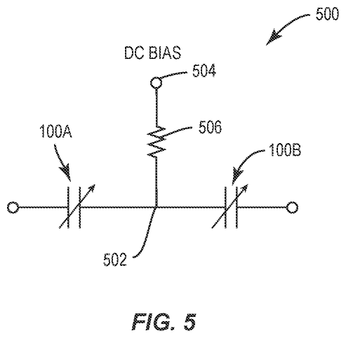

In many instances, the permittivity is set with a DC bias. However, there may be situations where this DC bias may negatively impact other elements in the circuit and it may be desirable to isolate the DC bias. Isolation circuit 500 illustrated in FIG. 5, may be used to provide such isolation. That is, a first varactor 100A is serially coupled to a second varactor 100B with a node 502 therebetween. A DC bias 504 is coupled to the node 502 through a resistance or inductance 506.

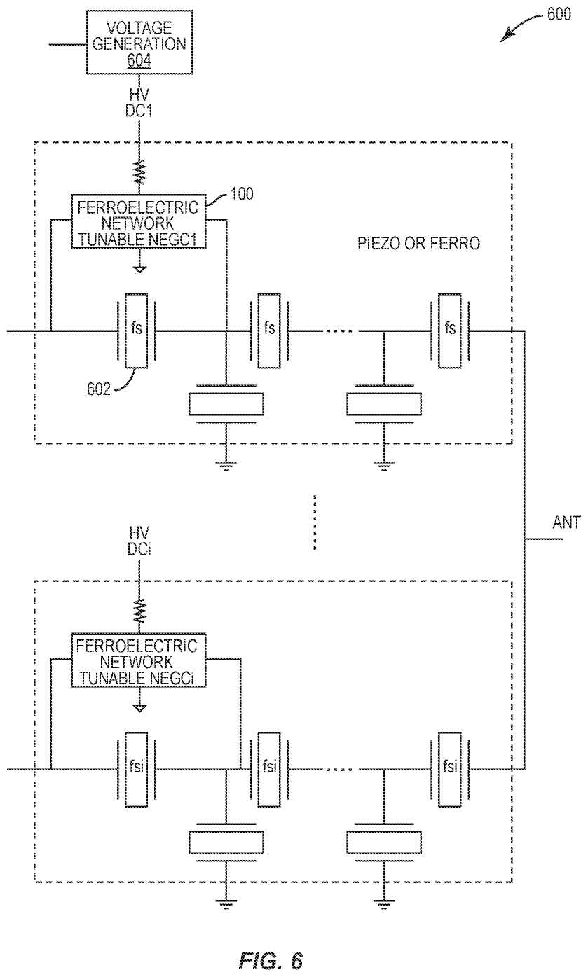

There are myriad uses for a varactor made according to aspects of the present disclosure, including resonators, oscillators (e.g., voltage-controlled oscillators (VCOs)), filters, or the like. One such use is provided in FIG. 6, where a varactor 100 is used in parallel with one or more resonator elements 602 in a ladder filter 600. The ladder filter 600 is an acoustic filter, and the ScAlN varactor 100 may be fabricated on the same die as other elements in the filter 600 or other circuits that use the filter 600. In general, aspects of the present disclosure allow for the fabrication of resonators and varactors on the same die using the same fabrication techniques.

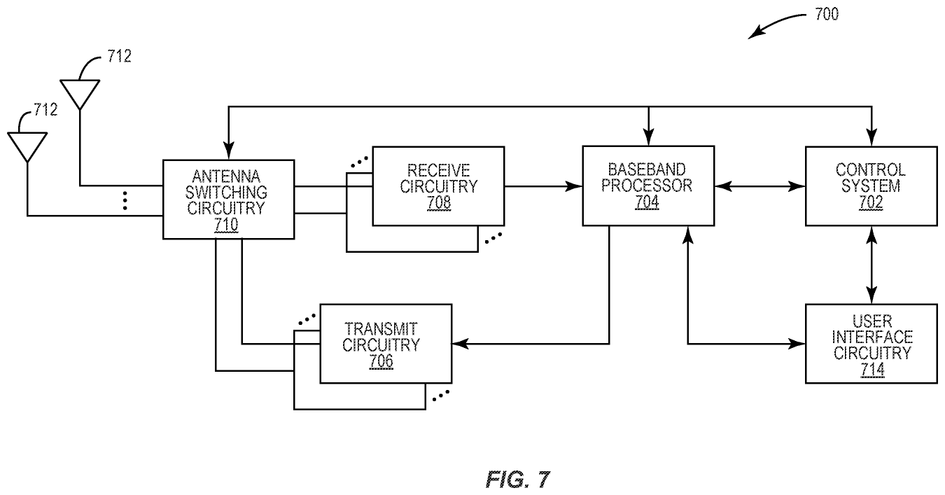

With reference to FIG. 7, the concepts described above may be implemented in various types of user elements 700, such as mobile terminals, smart watches, tablets, computers, navigation devices, access points, and like wireless communication devices that support wireless communications, such as cellular, wireless local area network (WLAN), Bluetooth, and near field communications. The user elements 700 will generally include a control system 702, a baseband processor 704, transmit circuitry 706, receive circuitry 708, antenna switching circuitry 710, multiple antennas 712, and user interface circuitry 714. In a non-limiting example, the control system 702 can be a field-programmable gate array (FPGA) or an application-specific integrated circuit (ASIC), as an example. In this regard, the control system 702 can include at least a microprocessor(s), an embedded memory circuit(s), and a communication bus interface(s). The receive circuitry 708 receives radio frequency signals via the antennas 712 and through the antenna switching circuitry 710 from one or more base stations. A low noise amplifier and a filter of the receive circuitry 708 cooperate to amplify and remove broadband interference from the received signal for processing. Downconversion and digitization circuitry (not shown) will then downconvert the filtered, received signal to an intermediate or baseband frequency signal, which is then digitized into one or more digital streams using an analog-to-digital converter(s) (ADC).

The baseband processor 704 processes the digitized received signal to extract the information or data bits conveyed in the received signal. This processing typically comprises demodulation, decoding, and error correction operations, as will be discussed on greater detail below. The baseband processor 704 is generally implemented in one or more digital signal processors (DSPs) and ASICs.

For transmission, the baseband processor 704 receives digitized data, which may represent voice, data, or control information, from the control system 702, which it encodes for transmission. The encoded data is output to the transmit circuitry 706, where a digital-to-analog converter(s) (DAC) converts the digitally-encoded data into an analog signal and a modulator modulates the analog signal onto a carrier signal that is at a desired transmit frequency or frequencies. A power amplifier will amplify the modulated carrier signal to a level appropriate for transmission and deliver the modulated carrier signal to the antennas 712 through the antenna switching circuitry 710 to the antennas 712. The multiple antennas 712 and the replicated transmit and receive circuitries 706, 708 may provide spatial diversity. Modulation and processing details will be understood by those skilled in the art.

Varactors according to the present disclosure may be used in VCOs that perform frequency upconversion or frequency downconversion, in filters or other resonators within the transmit or receive circuitry or the like.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein but is to be accorded the widest scope consistent with the principles and novel features disclosed herein.

What is claimed is:

1. A varactor comprising:
a ferroelectric material comprising scandium aluminum nitride (ScAlN);
a first electrode applied to the ferroelectric material; and
a second electrode applied to the ferroelectric material.

2. The varactor of claim 1, wherein the ferroelectric material comprises a first surface and a second surface, and the first electrode is positioned on the first surface and the second electrode is positioned on the second surface.

3. The varactor of claim 2, wherein the first surface is oppositely positioned relative to the second surface.

4. The varactor of claim 1, wherein the ferroelectric material comprises a first surface and the first electrode and the second electrode are positioned on the first surface in an interdigitated arrangement.

5. The varactor of claim 1, wherein the first electrode and the second electrode are positioned along a vertical side of the ferroelectric material.

6. The varactor of claim 4, wherein the ferroelectric material further comprises a second surface and wherein the varactor further comprises a third electrode and a fourth electrode positioned on the second surface in an interdigitated arrangement.

7. The varactor of claim 1 integrated into a filter.

8. The varactor of claim 1 integrated into a resonator.

9. The varactor of claim 1 integrated into an oscillator.

10. The varactor of claim 1, further comprising a direct current (DC) bias applied to the ferroelectric material to set a permittivity of the ferroelectric material.

11. A method of fabricating a die, comprising:
forming a varactor using a first ferroelectric material on a substrate; and
forming a resonator using a second ferroelectric material on the substrate.

12. The method of claim 11, wherein using the first ferroelectric material comprises using scandium aluminum nitride (ScAlN).

13. The method of claim 11, wherein forming the varactor comprises applying a first electrode to the ferroelectric material.

14. The method of claim 11, wherein the second ferroelectric material is the same material as the first ferroelectric material.

15. A mobile terminal comprising:
a transceiver comprising a varactor, the varactor comprising:
a ferroelectric material comprising scandium aluminum nitride (ScAlN);
a first electrode applied to the ferroelectric material; and
a second electrode applied to the ferroelectric material.

16. The mobile terminal of claim 15, wherein the ferroelectric material comprises a first surface and a second surface, and the first electrode is positioned on the first surface and the second electrode is positioned on the second surface.

17. The mobile terminal of claim 16, wherein the first surface is oppositely positioned relative to the second surface.

18. The mobile terminal of claim 15, wherein the ferroelectric material comprises a first surface and the first electrode and the second electrode are positioned on the first surface in an interdigitated arrangement.

19. The mobile terminal of claim 15, wherein the transceiver comprises a filter and the varactor is positioned in the filter.

20. The mobile terminal of claim 1, wherein the transceiver comprises a resonator and the varactor is positioned in the resonator.
